(19) United States
(12) Patent Application Publication
(10) Pub. No.: US 2005/0102465 A1
(43) Pub. Date: May 12, 2005

(54) Managing a cache with pinned data

(76) Inventor: Robert J. Royer, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/629,093

(22) Filed: Jul. 28, 2003

(51) Int. Cl. G11C 5/00

(52) U.S. Cl. 711/1

(57) ABSTRACT

In a Constant Access Time Bounded cache, reserving a first number of unallocated lines in the cache for pinned data, the first number being less than the number of lines in the cache; and if data needs to be inserted into the cache as pinned data, selecting a line from the lines reserved for pinned data; storing the data in the line; and inserting the line into a search group of the cache.

### BACKGROUND

Caching is a well-known technique that uses a smaller, faster storage device to speed up access to data stored in a larger, slower storage device. A typical application of caching is found in disk access technology. A processor based system accessing data on a hard disk drive, for example, may achieve improved performance if a cache implemented in solid state memory that has a lower access time than the drive is interposed between the drive and the processor. As is well known to those skilled in the art, such a cache is populated by data from the disk that is accessed by the system and subsequent accesses to the same data can then be made to the cache instead of to the disk, thereby speeding up performance. The use of caching imposes certain constraints on the design of a system, such as a requirement of cache consistency with the main storage device, e.g. when data is written to the cache, as well as performance based constraints which dictate, e.g. what parts of the cache are to be replaced when a data access is made to a data element that is not in the cache and the cache happens to be full (cache replacement policy).

A well known design for caches, specifically for disk caches, is an N-way set associative cache, where N is some non-zero whole number. In such a design, the cache may be implemented as a collection of N arrays of cache lines, each array representing a set, each set in turn having as members only such data elements, or, simply, elements, from the disk whose addresses map to that set based on an easily computed mapping function. Thus, in the case of a disk cache, any element on a disk can be quickly mapped to a set in the cache by, for example, obtaining the integer value resulting from performing a modulus of the address of the element on disk, its tag, with the number of sets, N, in the cache (the tag MOD N) the result being a number that uniquely maps the element to a set. Many other methods may be employed to map a line to a set in a cache, including bit shifting of the tag, or any other unique set of bits associated with the line, to obtain an index for a set; performing a logical AND between the tag or other unique identifier and a mask; XOR-ing the tag or other unique identifier with a mask to derive a set number, among others well known to those in skilled in the art, and the claimed subject matter is not limited to any one or more of these methods.

To locate an element in a set associative cache, the system uses the address of the data on the disk to compute the set in which the element would reside, and then in a typical implementation searches through the array representing the set until a match is found, or it is determined that the element is not in the set.

A similar implementation of a cache may use a hash table instead of associative sets to organize a cache. In such a cache, once again, elements are organized into fixed size arrays, usually of equal sizes. However, in this instance, a hashing function is used to compute the array within which an element is located. The input to the hashing function may be based on the element's tag and the function then maps the element to a particular hash bucket. Hashing functions and their uses for accessing data and cache organization are well known and are not discussed here in detail.

To simplify the exposition of the subject matter in this application, the term Constant Access Time Bounded (CATB) is introduced to describe cache designs including the set associative and hash table based caches described above. A key feature of CATB caches in the art is that they are organized into fixed sized arrays, generally of equal size, each of which is addressable in constant time based on some unique aspect of a cache element such as its tag. Other designs for CATB caches may be readily apparent to one skilled in the art. In general the access time to locate an element in a CATB cache is bounded by a constant, or at least is independent of the total cache size, because the time to identify an array is constant and each array is of a fixed size, and so searching within the array is bounded by a constant. For uniformity of terminology, the term search group is used to refer to the array (i.e. the set in a set associative cache or the hash bucket in the hash table based cache) that is identified by mapping an element.

Each element in a CATB cache, or cache line 120, contains both the actual data from the slower storage device that is being accessed by the system as well as some other data termed metadata that is used by the cache management system for administrative purposes. The metadata may include a tag i.e. the unique identifier or address for the data in the line, and other data relating to the state of the line including a bit or flag to indicate if the line is in use (allocated) or not in use (unallocated), as well as bits reserved for other purposes.

It may be advantageous for a certain line in the cache to always remain in the cache for as long as the system is in operation, for example, lines that contain often-accessed operating system code. Such cache lines are retained potentially indefinitely in the cache and are not subject to the normal cache replacement policy, and are said to be “pinned.” The cache management system will not remove that line from the cache when a demand for a new cache line is made for storage of new data coming into the cache. A line in such an implementation may have a flag in its metadata that indicates whether the line is pinned.

There are disadvantages associated with pinning, however. For reasons that are known and will not be discussed here in detail, CATB caches that have sets of approximately equal sizes may perform better than those with non-uniform set sizes. If one or more lines in a search group of a CATB cache, such as a set in a set-associative cache, become occupied by pinned data, the effective size of that search group for caching operations with non-pinned data becomes reduced by the number of pinned lines. If the system attempts to access data elements that are mapped to that search group, its performance may be reduced relative to its performance in accessing elements in other search groups that have no pinned elements. This phenomenon is termed hot spot creation and presents an issue for designers of caches with pinned lines.

### BRIEF DESCRIPTION OF THE DRAWINGS

FIG. 1 depicts a dynamic data structure that may be used to implement a N-way set associative cache.

FIG. 2 depicts the state of a data structure implementing an N-way set associative cache with a portion of the cache reserved for pinned data when no pinned data has been added to the cache, in accordance with an embodiment of the claimed subject matter

FIG. 3 depicts the state of the data structure from FIG. 2 after some pinned cache lines have been inserted into the cache, in an embodiment of the claimed subject matter.

FIG. 4 depicts a flowchart of actions taken to insert pinned data into the cache in one embodiment of the claimed subject matter

FIG. 5 depicts a flowchart of actions taken to reconstruct a cache following a power-down event in a non-volatile implementation in one embodiment of the claimed subject matter.

FIG. 6 depicts a processor based system in accordance with one embodiment of the claimed subject matter.

### DETAILED DESCRIPTION

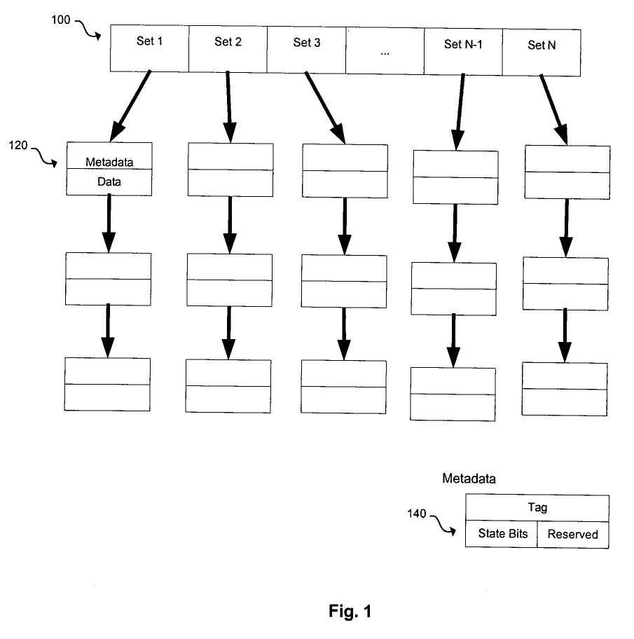

In one embodiment of the claimed subject matter, a dynamic data structure is used to implement a set associative cache, a type of CATB cache. In such an implementation, shown in FIG. 1, each set in the cache is implemented as a linked list 100. This list may be a singly or doubly linked list, in two exemplary embodiments. Each set contains cache lines 120, each cache line in turn having both data and metadata as shown at 140. Inserting, accessing and removing elements from this implementation of a cache may be accomplished by computing the identifier for a set using the tag of a cache line and then traversing the linked list corresponding to the set. If a line with the same tag is found, the element is in the cache; if not the element is not in the cache.

In this type of cache implementation, it is possible for the sets in the cache to all be of the same size, but it may also be possible to remove elements from or add elements to a set by removing a cache line from the linked list representing one set and linking it into another linked list, or conversely removing a cache line from a linked list separate from the lists representing the sets and adding it to a set. Thus in this cache implementation, sets may be of different sizes.

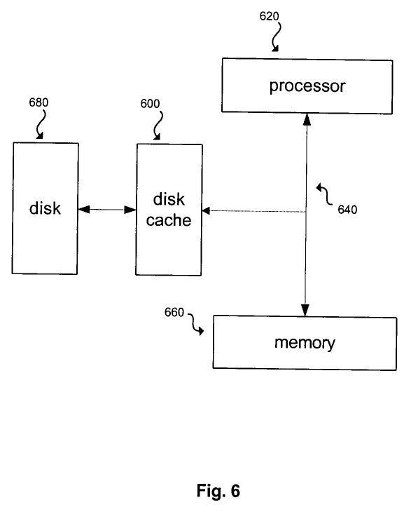

A processor based system such as the one depicted in FIG. 6 implements one exemplary embodiment of the claimed subject matter. The figure shows a processor 620 connected via a bus system 640 to a memory 660 and a disk and cache system including a disk 680 and a disk cache 600. In this implementation, the disk cache 600 may be implemented in volatile or in non-volatile memory. The processor may execute programs and access data, causing data to be read and written to disk 680 and consequently cached in disk cache 600. The system of FIG. 6 is of course merely representative. Many other variations on a processor based system are possible including variations in processor number, bus organization, memory organization, and number and types of disks. Furthermore, the claimed subject matter is not restricted to process based systems in particular, but may be extended to caches in general as described in the claims.

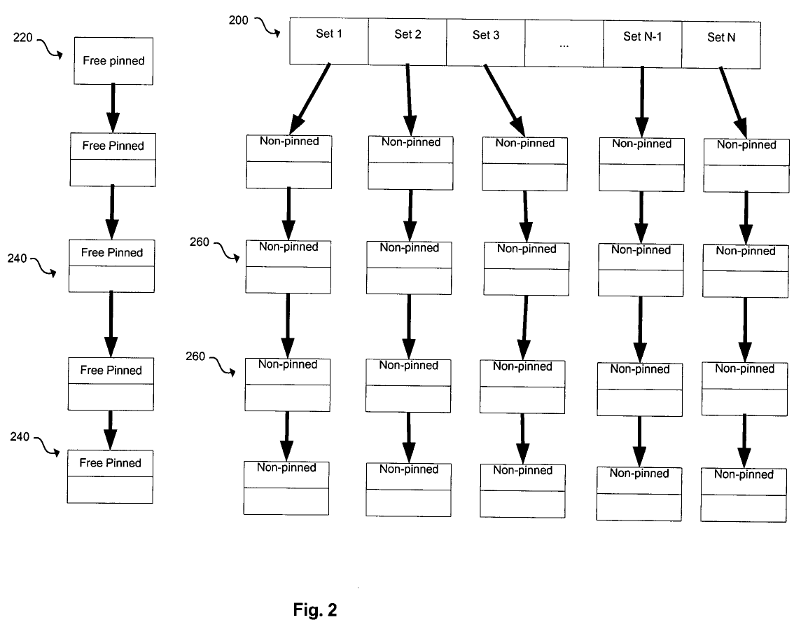

In the above referenced embodiment and in other embodiments of the claimed subject matter, a non-volatile memory unit may be used to implement a disk cache such as that depicted in FIG. 6 using a data structure like that discussed with reference to FIG. 1, but with a portion of the cache reserved for pinned data as shown in FIG. 2. In the figure, a portion of the unallocated cache line, termed the free pinned lines 240, is reserved for use with pinned data. These free pinned lines are placed in a free pinned linked list 220. The remaining cache lines 260 are allocated to N sets 200 in the usual manner for set associative caches.

In other embodiments in accordance with the claimed subject matter, a cache may be implemented in a volatile store unlike the embodiment discussed above. The cache may serve as a cache for purposes other than disk cache, e.g. a networked data or database cache.

The actual data structure used to organize the sets of the cache may also differ in some embodiments of the claimed subject matter. For example, the sets in the cache may not be of exactly equal sizes as is depicted in the figure.

The embodiment described above is limited to N-way set associative caches for ease of exposition and generally describes a dynamic implementation of such a cache. However, a list or other dynamic data structure may be used to make any type of CATB cache dynamic in an analogous manner. Thus, a hash table based CATB cache may also similarly be implemented using a dynamic structure such as a linked list of some type instead of an array for each hash bucket. In other embodiments of the claimed subject matter, in other CATB caches, a different basic search method may be used, as long as search times do not depend on the total number of elements in the cache and the individual search groups are dynamically variable in size.

Moreover, other terms such as ‘elements’ or ‘storage elements’ or ‘entries’ may be used to describe cache lines in other embodiments. These alternative embodiments are discussed to illustrate the many possible forms that an embodiment in accordance with the claimed subject matter may take and are not intended to limit the claimed subject matter only to the discussed embodiments.

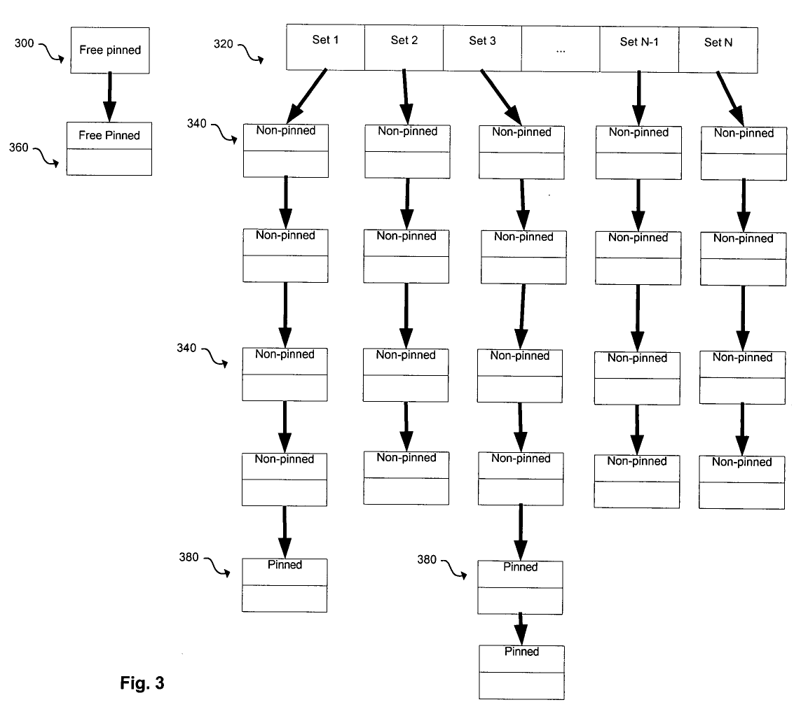

FIG. 3 depicts a snapshot of a set-associative cache implemented in an embodiment in accordance with the claimed subject matter as described above, during its operation. At this point in its operation, a number of pinned lines 380 have been added to the cache. When a pinned line is added, a free pinned line is removed from the free pinned list 300 and used to store the pinned line of data. As each pinned line is added to the cache, its tag is used to select one of the sets 320 into which it is to be inserted. After a pinned line has been added to the set it may be observed the number of non-pinned lines 340 in the set into which a pinned line has been inserted remains the same as before the insertion and that the number of non-pinned lines across the sets remains balanced. As the operation proceeds, the number of free pinned lines 360 may be reduced.

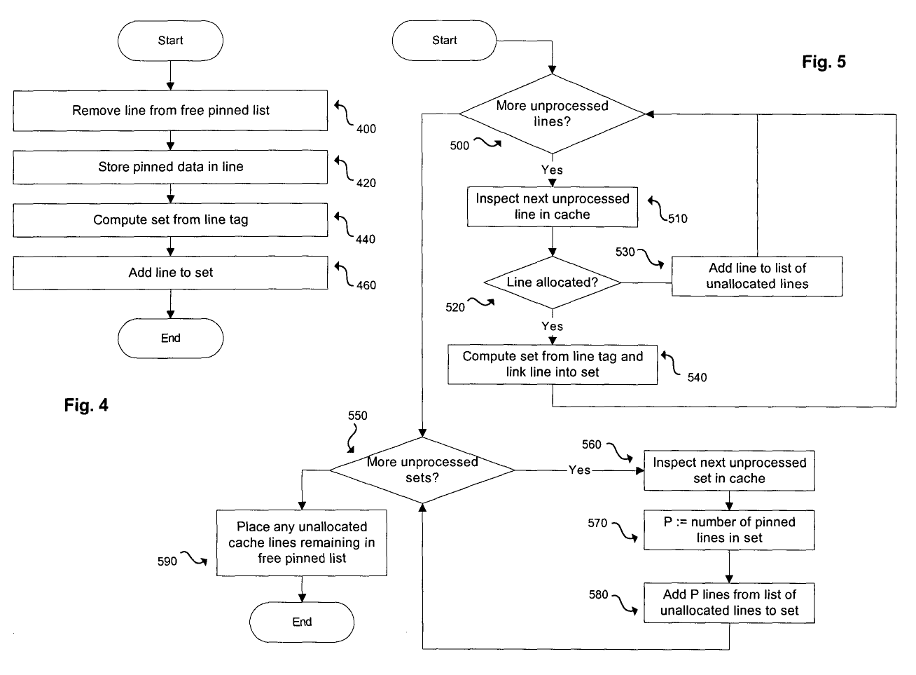

The operation of adding pinned data to the cache is further illustrated in the flowchart in FIG. 4. As new pinned data is added to the cache, the cache management system removes a line from the free pinned list 400, stores the pinned data in the line 420, computes the set into which the line should be inserted 440 and adds the line to the selected set 460.

As before this description of the operation of a cache embodying the claimed subject matter is not limiting. Many other embodiments are possible. For one example, data structures other than linked lists may be used to store the cache lines available for pinned data. While in this embodiment the non-pinned lines across the sets appear to stay equal, other embodiments may not maintain exact equality of the number of non-pinned lines across sets of the cache. In yet other embodiments, the number of lines allocated for pinned data may be dynamically variable during operation of the cache. As before, the operation may easily be generalized to other CATB caches. These alternative embodiments are discussed to illustrate the many possible forms that an embodiment in accordance with the claimed subject matter may take and are not intended to limit the claimed subject matter only to the discussed embodiments.

In implementations in some embodiments in accordance with the claimed subject matter, a set associative cache with a reserved list of pinned lines may be implemented in non-volatile memory, i.e. in a device that retains its data integrity after external power to the device is shut off as may happen if a system is shut down or in a power failure, thus causing a loss of power to the cache. This may include, in one exemplary embodiment, a cache implemented with non-volatile memory as a disk cache. In such an implementation, it may be possible to recover the state of the cache following a power-down event after power is restored. The addition of a reserved group of cache lines for pinned data does not impact such a recovery. FIG. 5 is a flowchart of a process that might be used to accomplish a recovery in an implementation of this nature.

In FIG. 5, a recovery process inspects each line in the non-volatile cache. As long as there are more lines to inspect, 500, the process inspects the next line 510. If the line has metadata in which the status information indicates that the line is allocated, i.e. contains valid cached data, it is inserted into the set identified by computing the set's identifier from the tag of the line, 540. If the line is unallocated, it may be added to a pool of unallocated lines in some manner, 530. When all lines are processed, the recovery then inspects each set formed in the first phase of the recovery. As long as there are more unprocessed sets 550, the next unprocessed set is inspected. For each line in the set that has metadata indicating that the line contains pinned data, the recovery procedure adds a line from the pool of unallocated lines to the set to maintain a balanced number of non-allocated lines across all sets, 570, 580. Any remaining lines are returned to the pool, 590.

Many other embodiments in accordance with the claimed subject matter relating to this recovery process are possible. For example, in some embodiments, the sets produced by the reconstruction process may not be exactly balanced. In others, the process of allocating allocated lines to sets may differ. The recovery process may be extended easily to CATB caches other than set-associative caches. These alternative embodiments are discussed to illustrate the many possible forms that an embodiment in accordance with the claimed subject matter may take and are not intended to limit the claimed subject matter only to the discussed embodiments.

Embodiments in accordance with the claimed subject matter include various steps. The steps in these embodiments may be performed by hardware devices, or may be embodied in machine-executable instructions, which may be used to cause a general-purpose or special-purpose processor or logic circuits programmed with the instructions to perform the steps. Alternatively, the steps may be performed by a combination of hardware and software. Embodiments in accordance with the claimed subject matter may be provided as a computer program product that may include a machine-readable medium having stored thereon data which when accessed by a machine may cause the machine to perform a process according to the claimed subject matter. The machine-readable medium may include, but is not limited to, floppy diskettes, optical disks, DVD-ROM disks, DVD-RAM disks, DVD-RW disks, DVD+RW disks, CD-R disks, CD-RW disks, CD-ROM disks, and magneto-optical disks, ROMs, RAMs, EPROMs, EEPROMs, magnet or optical cards, flash memory, or other type of media/machine-readable medium suitable for storing electronic instructions. Moreover, embodiments of the claimed subject matter may also be downloaded as a computer program product, wherein the program may be transferred from a remote computer to a requesting computer by way of data signals embodied in a carrier wave or other propagation medium via a communication link (e.g., a modem or network connection).

Many of the methods are described in their most basic form but steps can be added to or deleted from any of the methods and information can be added or subtracted from any of the described messages without departing from the basic scope of the claimed subject matter. It will be apparent to those skilled in the art that many further modifications and adaptations can be made. The particular embodiments are not provided to limit the invention but to illustrate it. The scope of the claimed subject matter is not to be determined by the specific examples provided above but only by the claims below.

1. In a Constant Access Time Bounded (CATB) cache, a method comprising:
reserving a first number of unallocated lines in the cache for pinned data, the first number being less than the number of lines in the cache; and
if data needs to be inserted into the cache as pinned data,
selecting a line from the lines reserved for pinned data;
storing the data in the line; and
inserting the line into a search group of the CATB cache.

2. The method of claim 1 wherein each line of the cache is stored in non-volatile memory.

3. The method of claim 2 further comprising:
recovering the organization of the cache on power up following a loss of power to the cache by
in a first phase of recovery, for each line in the cache
determining if the line is allocated;
if the line is allocated, inserting the line in a search group of the cache; and
if the line is not allocated, inserting the line into a pool of free lines; and
in a second phase of recovery, for each search group
determining the number of pinned lines in the search group; and
adding at least one line from the pool of free lines to each search group that has at least one pinned line.

4. The method of claim 3 wherein the cache is a disk cache in a processor based system.

5. The method of claim 1 wherein inserting the line into a search group of the cache further comprises:
indicating that the line is allocated;
indicating that the line is pinned; and
using a tag of the line to map the line to a search group of the cache.

6. The method of claim 5 wherein:
the CATB cache is implemented as a set-associative cache;
each search group of the cache is a set of the cache; and
inserting the line into a search group of the cache further comprises:
using the address of the data as the tag of the line;
performing a modulus operation between the tag and the number of sets (N) in the cache (the tag MOD N) to map the tag to a set of the cache;
performing a search based on the tag of the line; and
inserting the line into a dynamic data structure that represents the set.

7. The method of claim 6 wherein indicating that the line is pinned further comprises modifying metadata associated with the line to indicate that the line is pinned.

8. For a whole number N, in an N-way set associative non-volatile disk cache, a method comprising:
reserving a predetermined number of lines for pinned data and organizing them into a pool of lines for pinned data;
distributing the remaining lines in the cache into N dynamic data structures of approximately the same size to represent the N sets of the cache;
if data is to be inserted into the cache as pinned data,
inserting the data into a line from the pool for pinned data;
marking the line as allocated by modifying metadata associated with the line;
determining the set to which the line belongs using a mapping based on the tag associated with the line;
removing the line from the pool for pinned data; and
adding the line to the set.

9. The method of claim 8 further comprising:
recovering the organization of the cache on power up following a loss of power to the cache by
in a first phase of recovery, for each line in the cache
determining if the line is allocated;
if the line is allocated, inserting the line in a set of the cache using a mapping based on the tag associated with the line; and
if the line is not allocated, inserting the line into a pool of unallocated lines; and
in a second phase of recovery, for each set in the cache
determining the number of pinned lines in the set using the metadata associated with each line in the set; and
moving one or more lines from the pool of unallocated lines to each set that has at least one pinned line so that the number of non-pinned lines in each set is approximately the same.

10. An apparatus comprising:
an N-way set associative cache implemented in non-volatile memory a pinned data portion of the non-volatile memory to store a pool of lines for pinned data; and
a pinned data insertion module to
insert pinned data into a line from the pool of lines for pinned data;
mark the line as being allocated by modifying metadata associated with the line;
determine a set to which the line belongs using a mapping based on the tag associated with the line;
remove the line from the pool for pinned data; and
add the line to the set.

11. The apparatus of claim 10 further comprising
a power source to provide power to the cache; and
a recovery module to recover the organization of the cache on power up following a loss of power to the cache from the power source by
in a first phase of recovery, for each line in the cache
determining if the line is allocated;
if the line is allocated, inserting the line in a set of the cache using a mapping based on the tag associated with the line; and
if the line is not allocated, inserting the line into a pool of unallocated lines; and
in a second phase of recovery, for each set in the cache
determining the number of pinned lines in the set using the metadata associated with each line in the set; and
moving one or more lines from the pool of unallocated lines to each set that has at least one pinned line so that the number of non-pinned lines in each set is approximately the same.

12. A system comprising
a processor;
a disk communicatively coupled to the processor;
an N-way set associative cache implemented in non-volatile battery-backed up Dynamic Random Access Memory communicatively coupled to the processor;
a pinned data portion of the non-volatile flash memory to store a pool of lines for pinned data; and
a pinned data insertion module to
insert pinned data into a line from the pool of lines for pinned data;
mark the line as being allocated by modifying metadata associated with the line;
determine a set into which the line using a mapping based on the tag associated with the line;
remove the line from the pool for pinned data; and
add the line to the set.

13. A machine readable medium having stored thereon data which when accessed by a machine causes the machine to perform the method of claim 1.

14. The machine readable medium of claim 13 having stored thereon further data which when accessed by a machine causes the machine to perform the method of claim 2.

15. The machine readable medium of claim 14 having stored thereon further data which when accessed by a machine causes the machine to perform the method of claim 3.

16. The machine readable medium of claim 15 having stored thereon further data which when accessed by a machine causes the machine to perform the method of claim 4.

17. The machine readable medium of claim 13 having stored thereon further data which when accessed by a machine causes the machine to perform the method of claim 5.

18. The machine readable medium of claim 17 having stored thereon further data which when accessed by a machine causes the machine to perform the method of claim 6.

19. The machine readable medium of claim 18 having stored thereon further data which when accessed by a machine causes the machine to perform the method of claim 7.

20. A machine readable medium having stored thereon data which when accessed by a machine causes the machine to perform the method of claim 8.

21. The machine readable medium of claim 20 having stored thereon further data which when accessed by a machine causes the machine to perform the method of claim 9.

22. In a Constant Access Time Bounded (CATB) cache, a method comprising:
initializing a search group of the CATB cache with a capability to dynamically insert and delete elements; and
inserting elements dynamically into the search group of the CATB.

23. The method of claim 22 further comprising:
receiving a first identifier for an element;
using the first identifier to compute a second identifier for a search group in the CATB cache; and
traversing the search group to locate an element matching the first identifier.

24. The method of claim 23 wherein the search group is implemented as a linked list.

25. A machine readable medium having stored thereon data which when accessed by a machine causes the machine to perform the method of claim 22.

26. The machine readable medium of claim 25 having stored thereon further data which when accessed by a machine causes the machine to perform the method of claim 23.

27. The machine readable medium of claim 25 having stored thereon further data which when accessed by a machine causes the machine to perform the method of claim 24.
